(19) United States
(12) Patent Application Publication
(10) Pub. No.: US 2026/0163531 A1
(43) Pub. Date: Jun. 11, 2026

(54) LOW-NOISE AMPLIFIER FOR MICRO-ELECTRO-MECHANICAL SYSTEMS (MEMS) MICROPHONES

(71) Applicant: CIRRUS LOGIC INTERNATIONAL SEMICONDUCTOR LTD., Edinburgh (GB)

(72) Inventors: Axel Thomsen, Austin, TX (US); Paul Wilson, Linlithgow (GB); Aleksey Khenkin, Austin, TX (US)

(21) Appl. No.: 19/348,566

(22) Filed: Oct. 2, 2025

Related U.S. Application Data
(60) Provisional application No. 63/728,936, filed on Dec. 6, 2024.

(51) Int. Cl. H03F 1/26; H03F 3/45; H04R 19/00

(52) U.S. Cl. CPC H03F 1/26; H03F 3/45475; H04R 19/005; H03F 2200/03; H03F 2200/294; H04R 2201/003

(57) ABSTRACT

Extended dynamic range of a Micro-Electro-Mechanical System (MEMS) microphone circuit is accomplished in low-noise amplifier circuits and their methods of operation. The circuits are amplifier circuits that receive an input signal from a MEMS microphone, and include an input terminal for connection to a terminal of the MEMS microphone, a low-noise amplifier that has an input coupled to the input terminal, and an inverting charge pump circuit that generates a negative power supply voltage from an external positive voltage power supply. An output of the inverting charge pump circuit is coupled to a negative power supply terminal of the low-noise amplifier. In some embodiments, the MEMS microphone has a pair of terminals that are coupled to a pair of input terminals of the low-noise amplifier, which is a low-noise differential amplifier.

### BACKGROUND

### 1. Field of Disclosure

The field of representative embodiments of this disclosure relates to low-noise amplifiers, and in particular to a low-noise amplifier for amplifying signals provided from micro-electro-mechanical systems (MEMS) microphones.

### 2. Background

Micro-Electro-Mechanical Systems (MEMS) are seeing increasing use to provide acoustic input, due to their typically compact relative size, low power consumption, and their implementation allowing for integration on a semiconductor die with other circuits, or on a common substrate to be packaged together with associated circuits. MEMS microphones are also desirable in some applications that require directionality and noise-cancellation, because signals from the elements that make up the MEMS array may be combined in such a way that a directional or tunable microphone pattern is generated.

MEMS microphone elements typically require a power supply voltage for operation that is greater than that of, for example, battery operated portable devices such as mobile telephones and tablets, which poses challenges for operation and design of the measurement circuit, which are typically integrated with the MEMS microphone element. If the wide voltage range produced at the output of a MEMS microphone is not addressed, signal clipping at the receiving circuit, or the dynamic range of the microphone must be limited, e.g., by applying passive attenuation prior to amplification. Such attenuation reduces the actual dynamic range of the microphone, since the noise floor is raised relative to the output signal.

Therefore, it would be advantageous to provide a MEMS microphone amplification circuit that provides extended dynamic range without clipping or otherwise unacceptably distorting the microphone output signal.

### SUMMARY

Extended dynamic range of a Micro-Electro-Mechanical System (MEMS) microphone circuit is accomplished in low-noise amplifier circuits and integrated circuits and systems including the amplifier circuits, along with their methods of operation.

The circuit is an amplifier circuit that receives an input signal from a MEMS microphone, and includes an input terminal for connection to a terminal of the MEMS microphone, a low-noise amplifier that has an input coupled to the input terminal, and an inverting charge pump circuit that generates a negative power supply voltage from an external positive voltage power supply. An output of the inverting charge pump circuit is coupled to a negative power supply terminal of the low-noise amplifier. In some embodiments, the MEMS microphone has a pair of terminals that are coupled to a pair of input terminals of the low-noise amplifier, which is a low-noise differential amplifier.

The summary above is provided for brief explanation and does not restrict the scope of the claims. The description below sets forth example embodiments according to this disclosure. Further embodiments and implementations will be apparent to those having ordinary skill in the art. Persons having ordinary skill in the art will recognize that various equivalent techniques may be applied in lieu of, or in conjunction with, the embodiments discussed below, and all such equivalents are encompassed by the present disclosure.

### BRIEF DESCRIPTION OF THE DRAWINGS

FIG. 1A is pictorial diagram illustrating an example device 10, in accordance with embodiments of the disclosure.

FIG. 1B is a block diagram illustrating an example MEMS microphone 12 that may be used to implement MEMS microphones 12A,12B of FIG. 1A, in accordance with embodiments of the disclosure.

FIG. 2 is a block diagram illustrating an example MEMS microphone measurement circuit 30, that may be used to implement a portion of application-specific integrated circuit (ASIC) 20 in example MEMS microphone 12 of FIG. 1B, in accordance with an embodiment of the disclosure.

FIG. 3 is a simplified schematic diagram illustrating an example MEMS microphone measurement circuit 40, that may be used to implement example MEMS microphone measurement circuit 30 of FIG. 2, in accordance with an embodiment of the disclosure.

FIG. 4 is a simplified schematic diagram of an example negative charge pump circuit 50 that may be used to implement negative charge pump circuit 34 in example MEMS microphone measurement circuit 30 of FIG. 2, in accordance with an embodiment of the disclosure.

FIG. 5 is a simplified schematic diagram illustrating another example MEMS microphone measurement circuit 60, that may be used to implement example MEMS microphone measurement circuit 30 of FIG. 2, in accordance with another embodiment of the disclosure.

FIG. 6 is a simplified schematic diagram illustrating an example protected chopped capacitively-coupled instrumentation amplifier (CCIA) circuit 70, that may be used to implement overload protection in example MEMS microphone measurement circuit 60 of FIG. 5 in accordance with an embodiment of the disclosure.

FIG. 7 is a simplified schematic diagram illustrating another example MEMS microphone measurement circuit 80, that may be used to implement example MEMS microphone measurement circuit 30 of FIG. 2, in accordance with another embodiment of the disclosure.

### DESCRIPTION OF ILLUSTRATIVE EMBODIMENT

The present disclosure encompasses circuits and integrated circuits that include improved low-noise amplifiers for receiving MEMS microphone output signals and their method of operation. Extended dynamic range is accomplished in low-noise amplifier circuits and integrated circuits and systems including the amplifier circuits, along with their methods of operation. The circuits are amplifier circuits that receive an input signal from a MEMS microphone, and include an input terminal for connection to a terminal of the MEMS microphone, a low-noise amplifier that has an input coupled to the input terminal, and an inverting charge pump circuit that generates a negative power supply voltage from an external positive voltage power supply. An output of the inverting charge pump circuit is coupled to a negative power supply terminal of the low-noise amplifier. In some embodiments, the MEMS microphone has a pair of terminals that are coupled to a pair of input terminals of the low-noise amplifier, which is a low-noise differential amplifier.

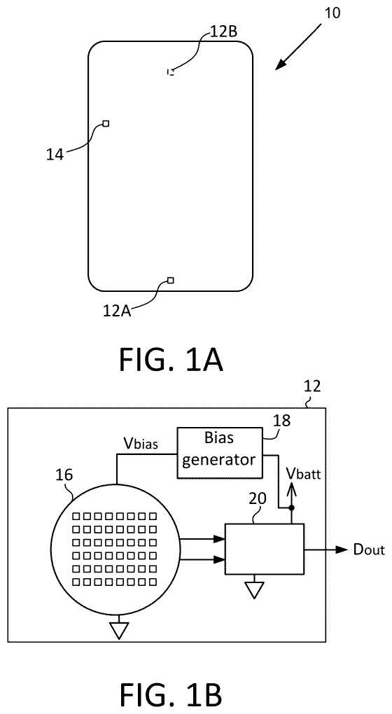

Referring now to FIG. 1A, a pictorial diagram illustrating an example device 10, is shown in accordance with embodiments of the disclosure. Example handheld device 10, which may be a mobile device such as a smart phone, tablet, or notebook computer, and includes multiple MEMS elements, such as a MEMS microphone 12A used to capture a user's voice and a MEMS microphone 12B, which may be on the rear of the device, used to measure noise-canceling performance and/or to provide ambient sound measurement separate from the user's voice. Other MEMS elements 14 may include accelerometers and/or gyroscopes, which may also benefit from the techniques disclosed herein.

Referring now to FIG. 1B, a block diagram illustrating an example MEMS microphone 12 that may be used to implement MEMS microphones 12A,12B of FIG. 1A, is shown in accordance with embodiments of the disclosure. A MEMS microphone 16 is coupled to an application-specific integrated circuit (ASIC) that receives output signals from MEMS microphone 16 and generates a digital output Dₒᵤₜ that represents the acoustic environment present at the face of MEMS microphone array 16. A bias generator 18, which may be provided by a boost converter or voltage multiplier, provides an operating bias voltage V_{bias} to MEMS microphone element 12. Bias voltage V_{bias} is generally much greater than an operating power supply voltage V_{batt} provided to ASIC 20, for example, bias voltage V_{bias} may be 20V, while power supply voltage V_{batt} may be 1.8V.

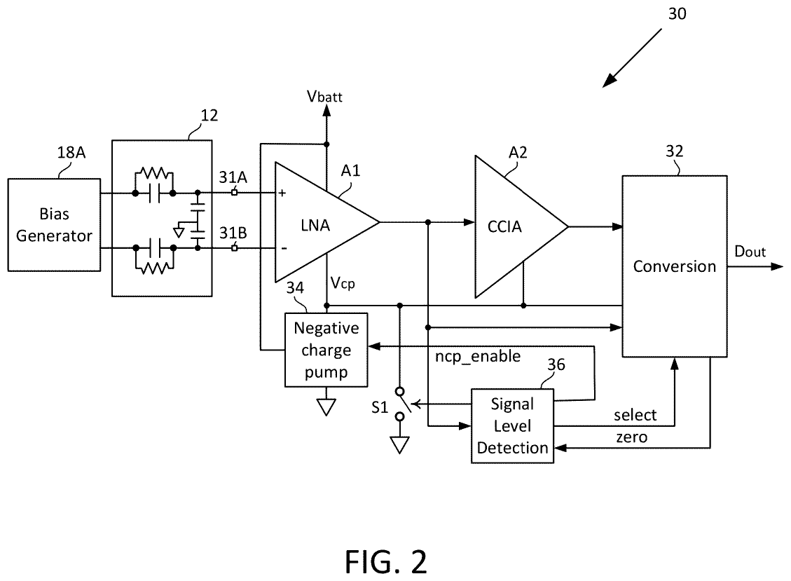

Referring now to FIG. 2, a block diagram illustrating an example MEMS microphone measurement circuit 30, that may be used to implement a portion of application-specific integrated circuit (ASIC) 20 in example MEMS microphone 12 of FIG. 1B, is shown in accordance with an embodiment of the disclosure. A bias generator 18A provides a bias voltage to MEMS microphone element 12. MEMS microphone element 12 provides a pair of outputs from a pair of terminals 31A, 31B to a low-noise amplifier (LNA) A1. LNA A1 is operated from power supply voltage V_{batt} at a positive power supply terminal, and a negative power supply voltage V_{cp} provided by a negative charge pump circuit 34, which may be, for example an approximately invert of power supply voltage V_{batt} with respect to ground, which, in the example, provides the common-mode potential. E.g., negative power supply voltage V_{cp} may be approximately −1.8V. The output of LNA A1 is provided to an input(s) of a chopped capacitively-coupled instrumentation amplifier (CCIA) A2, which will generally be a fully-differential amplifier. Both the output(s) of LNA A1 and the output(s) or CCIA A2 are provided to a conversion block 32, which, in accordance with an embodiment of the disclosure, selects between LNA A1 and CCIA A2, for providing digital output D_{OUT}, so that the output of LNA A1 may be used to provide an additional signal path that bypasses CCIA A2 to provide the source of digital output D_{OUT}, and provides an alternative signal path when signal levels from the output of MEMS microphone 12 are greater in amplitude. The output of CCIA A2 provides the source of digital output D_{OUT} when signal levels from the output of MEMS microphone 12 are lower in amplitude. A signal level detection block 36 provides the selection input to conversion block 32 to perform the selection, as well as optionally providing a power management control signal ncp_enable to disable negative charge pump 34 and activate a switch S1 to connect the negative power supply rail of LNA A1 to ground, when signal levels are lower than the threshold. The signal-level-dependent selection of the higher gain signal path, along with the provision of a negative supply voltage generated from the input power supply, provides for handling of higher amplitude signals. The detection by signal level detection block 36 may include peak detection, root-means-square detection, or other suitable signal level detection technique, and the control will generally include hysteresis to prevent rapid alternation between signal paths. Selection may also be performed gradually, for example, by combining the signals from the signal paths according to a progressive weighting function, such as the weighted transition described in U.S. Pat. No. 10,263,630 entitled “Multi-path analog front end with adaptive path”, the disclosure of which is incorporated herein by reference. Example MEMS microphone measurement circuit 30 also provides a wider dynamic range without requiring attenuation of the output signal of MEMS microphone 12, and thus a higher noise floor, or otherwise introducing distortion in the signal due to overload of the amplification path. A zero-cross detection signal zero provided from the digital portion of conversion block 32 to signal level detection block 36 may be used to synchronize signal path selection changes and also reset overload protection clamping circuits as described below.

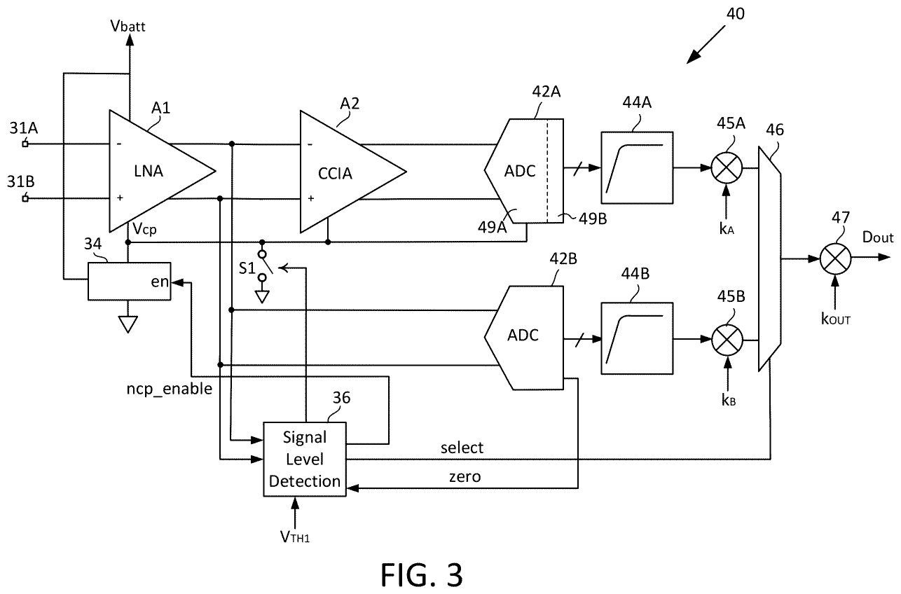

Referring now to FIG. 3, a simplified schematic diagram of an example negative charge pump circuit 40 that may be used to implement negative charge pump circuit 36 in example MEMS microphone measurement circuit 30 of FIG. 2, is shown in accordance with an embodiment of the disclosure. A MEMS microphone output signal is received by terminals 31A, 31B and is amplified by LNA A1, which has a negative power supply rail Vcp supplied by negative charge pump circuit 34 as described above. Negative power supply rail Vcp is also supplied to CCIA A2, or at least the input switching network thereof, and to input sampling stage portions 49A of ADC 42A to maintain compatibility with all of the signal levels that may be generated from LNA A1. LNA A1 has a differential output that is coupled to CCIA A2. The differential outputs of LNA A1 are also coupled to an analog-to-digital converter (ADC) 42B, which provides conversion of the additional low-gain analog path that bypasses CCIA A2 to provide a digital signal along an alternative signal path. The digital signal is then filtered by a high-pass filter 44B and gain-adjusted by a multiplier 45B, which applies a gain (or attenuation) k_{B}. A high-gain signal path is provided through CCIA A2 with outputs coupled to an ADC 42A, which provides conversion of the high-gain analog path to another digital signal, which is filtered by a high-pass filter 44A and gain-adjusted by a multiplier 45A, which applies a gain (or attenuation) k_{A}. A multiplexer 46 selects between the low-gain signal path and the high-gain signal path according to control signal select provided from signal level detection block 36, which determines whether or not the signal level at one or both outputs of LNA A1 exceeds a threshold voltage V_{TH1}. The output of multiplexer 46 is scaled by another multiplier 47 that applies a gain (or attenuation) value k_{OUT} to provide digital output signal Dₒᵤₜ.

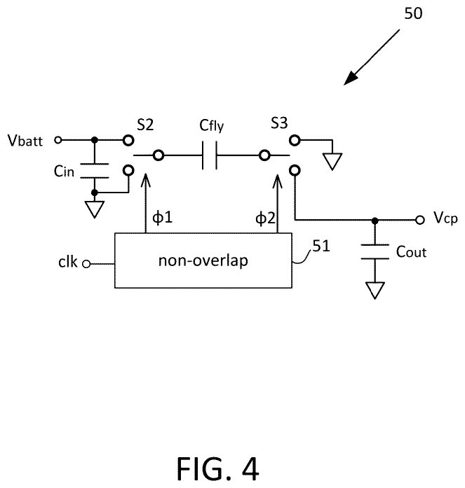

Referring now to FIG. 4, a simplified schematic diagram of an example negative charge pump circuit 50 that may be used to implement negative charge pump circuit 36 in example MEMS microphone measurement circuit 30 of FIG. 2, is shown in accordance with an embodiment of the disclosure. Positive power supply voltage V_{batt} is applied across an input capacitor Cᵢₙ and a switch S2 alternatively connects a flyback capacitor C_{fly} between the common-mode voltage (shown as ground) and positive power supply voltage V_{batt}, according to a first phase φ1 of a clock generated by a non-overlap clock generator 51 from an input clock signal clk. A second switch S3 alternatively connects flyback capacitor C_{fly} to the common-mode voltage, while switch S2 connects the other terminal of flyback capacitor C_{fly} to power supply voltage V_{batt}, and then to the output that carries negative power supply voltage V_{cp} while switch S2 connects the other terminal of flyback capacitor C_{fly} to the common-mode voltage, according to a second phase φ2 of the clock generated by a non-overlap clock generator 51. The resulting operation charges an output capacitor Cout to approximately an inverted version of positive power supply voltage V_{batt}, less any circuit losses.

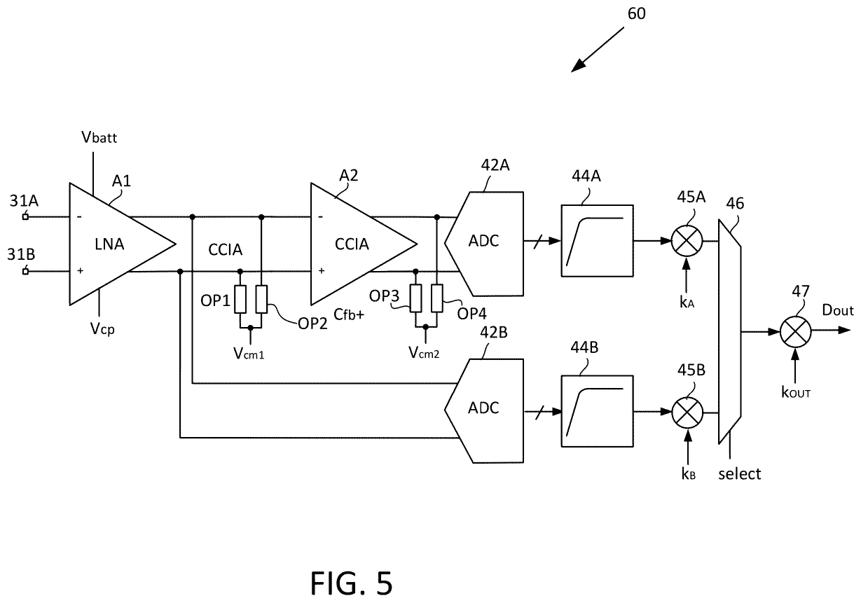

Referring now to FIG. 5, a simplified schematic diagram illustrating another example MEMS microphone measurement circuit 60, that may be used to implement example MEMS microphone measurement circuit 30 of FIG. 2, is shown in accordance with another embodiment of the disclosure. Example MEMS microphone measurement circuit 60 is similar to example MEMS microphone measurement circuit 40 of FIG. 3, so only differences between the circuits will be described in detail below. When high input signal levels are present at terminals 31A, 31B, causing selection of the low-gain signal path through ADC 42B, the activity present at CCIA A2 may cause signal distortion, because the high signal levels are still present at input capacitors Cᵢₙ₋,Cᵢₙ₊, and CCIA A2 may operate out of its linear region and cause spurious/saturated voltage values across feedback capacitors C_{fb-}, C_{fb+}, all of which may be reflected back to the outputs of LNA A1. To prevent such mis-operation, overload protection circuits OP1 and OP2 are present at the summing junctions at the inputs of CCIA A2, and overload protection circuits OP3 and OP4 may also be located at the outputs of CCIA A2. Overload protection circuits OP1 and OP2 force the voltages at the input summing nodes of CCIA A2 to a first common-mode voltage V_{CM1}, which is generally the input common mode voltage of CCIA A2, and which may differ from the common mode voltage at the inputs of LNA A1. Optionally, overload protection circuits OP3 and OP4 force the voltages at the differential outputs of CCIA A2 to another common-mode voltage (V_{CM2}), and thus the voltage across feedback capacitors C_{fb-}, C_{fb+} is forced to a direct-current (DC) voltage (e.g., |V_{CM1}−V_{CM2}|), by action of all of overload protection circuits OP1-OP4. In general, overload protection circuits OP1-OP4 are activated when a potential signal overload is detected by signal level detector 36 and is only reset when the signal level has decreased and at the time of a zero-crossing in the signal as described above.

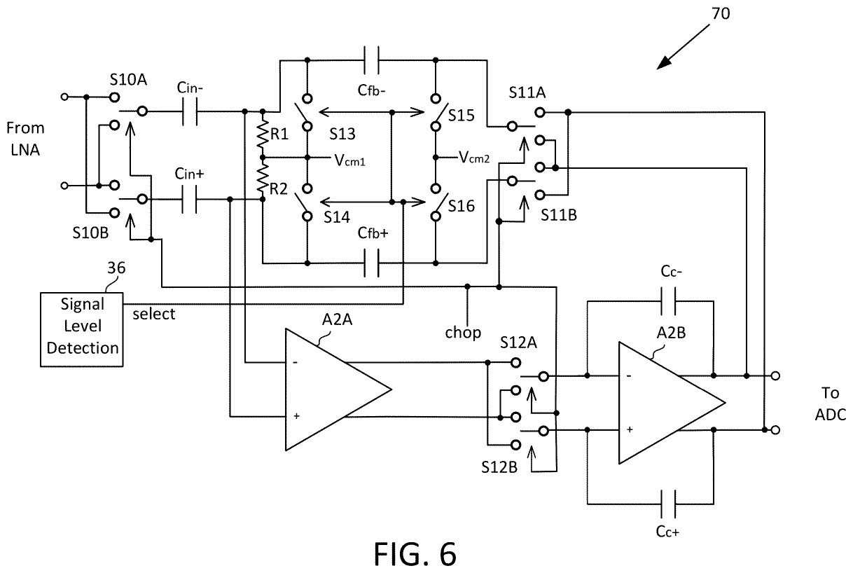

Referring now to FIG. 6, a simplified schematic diagram illustrating an example protected CCIA circuit 70, that may be used to implement overload protection in example MEMS microphone measurement circuit 60 of FIG. 5, is shown in accordance with an embodiment of the disclosure. A pair of chopping switches S10A, S10B chop the input signal that is provided to a pair of input capacitors Cᵢₙ₋,Cᵢₙ₊, which provide a low-noise alternative to typical resistive coupling. A pair of resistors R1, R2 reference the summing nodes of a first amplifier stage A2A to common-mode voltage V_{cm1}. A pair of feedback capacitors C_{fb-}, C_{fb+} that set the gain of CCIA circuit 70, are coupled to their respective summing nodes of first amplifier stage A2A and their connections to the output of example protected CCIA circuit 70 are chopped by another pair of chopping switches S11A, S11B. The output of example protected CCIA circuit 70 is provided by a second amplifier stage A2B that has an input coupled from the output of first amplifier stage A2A by a third pair of chopping switches S12A, S12B, and feedback compensation provided by a pair of capacitors C_{c-}, C_{c+}. The chopping actions of switches S10A, S10B, S11A, S11B, S12A, and S12B are controlled by a high-frequency chopping clock signal chop, which removes any offset introduced in the signal path of example protected CCIA circuit 70 and shifts low frequency noise (flicker noise) out of the audio frequency band (or other frequency band of interest). Overload protection is provided by switches S13, S14, S15, and S16, which clamp the input summing nodes of first amplifier stage A2A and the first terminals of feedback capacitors C_{fb-}, C_{fb+} to common-mode voltage V_{CM1} and the second terminals of feedback capacitors C_{fb-}, C_{fb+} to common-mode voltage V_{CM2}.

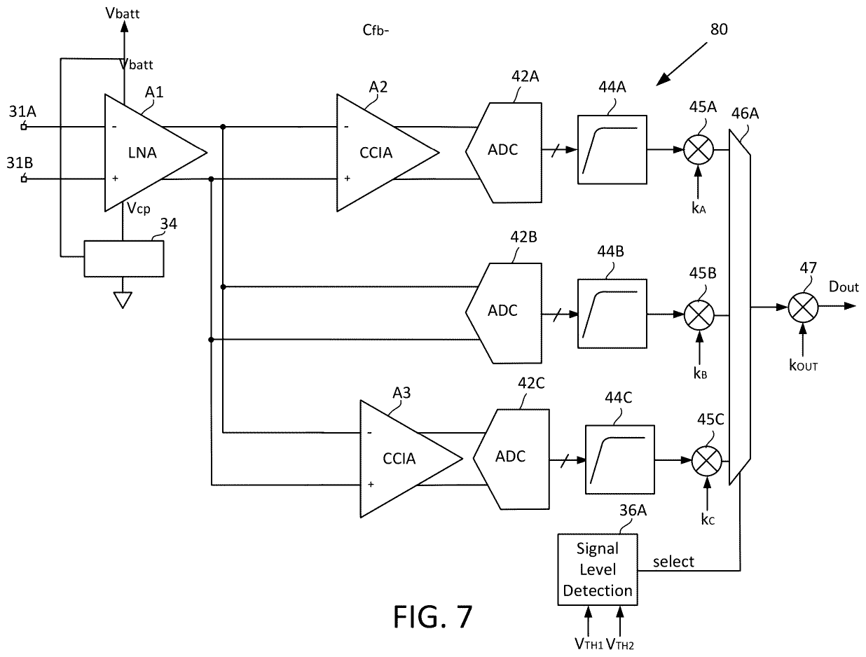

Referring now to FIG. 7, a simplified schematic diagram illustrating another example MEMS microphone measurement circuit 80, that may be used to implement example MEMS microphone measurement circuit 30 of FIG. 2, is shown in accordance with another embodiment of the disclosure. Example MEMS microphone measurement circuit 80 is similar to example MEMS microphone measurement circuit 40 of FIG. 3, so only differences between the circuits will be described in detail below. Example MEMS microphone measurement circuit 80 is an example of a MEMS microphone measurement circuit having more than two signal paths, which in the illustrated example, are selected by a multiplexer 46A according to outputs of a signal level detection block 36A that indicate whether the signal level is less than a pair of differing voltage thresholds V_{TH1}, V_{TH2}, between them, or greater than voltage thresholds V_{TH1}, V_{TH2}. If the input signal level is less than both voltage thresholds V_{TH1}, V_{TH2}, the high-gain signal path through CCIA A2, ADC 42A, high-pass filter 44A and multiplier 45A is selected, as described above with reference to FIG. 3. If the signal level is greater than both voltage thresholds V_{TH1}, V_{TH2}, the low-gain signal path through ADC 42B, high-pass filter 44B and multiplier 45B is selected, as described above with reference to FIG. 3. If the signal level is between voltage thresholds V_{TH1}, V_{TH2}, an intermediate-gain signal path through a second CCIA A3, an ADC 42C, high-pass filter 44C and multiplier 45C that applies a gain/attenuation value kc is selected, providing a wider range of channels for handling input signal levels of various amplitudes. Multiplexer 46A may be a single multiplexer, or may be a cascade of multiplexers acting as a single multiplexer, and ADCs may be shared between signal paths, for example, a multiplexer may first separately select between the signal paths including CCIAs A2 and A3 prior to conversion, with the output of the multiplexer provided to the input of ADC 42B.

In summary, this disclosure shows and describes circuits, and their methods of operation, that increase the dynamic range of a microphone channel that receives a MEMS microphone input. The circuits have at least one input terminal for connection to at least one terminal of the MEMS microphone, a low-noise amplifier having an input coupled to the at least one input terminal, and an inverting charge pump circuit for generating a negative power supply voltage from an external positive voltage power supply, wherein an output of the inverting charge pump circuit is coupled to a negative power supply terminal of the low-noise amplifier.

In some example embodiments, the at least one terminal of the MEMS microphone may be a pair of terminals of the MEMS microphone, the at least one input terminal may be a pair of input terminals for connection to the pair of terminals of the MEMS microphone, and the low-noise amplifier may be a low-noise differential amplifier having a pair of inputs coupled to the pair of input terminals. In some example embodiments, the low-noise differential amplifier may be DC coupled to the MEMS microphone by connection of the pair of inputs of the low-noise differential amplifier to the pair of input terminals. In some example embodiments, a pair of differential outputs of the low-noise differential amplifier may be coupled to corresponding inputs of a capacitively-coupled instrumentation amplifier (CCIA).

In some example embodiments, the circuits may include a first analog-to-digital converter (ADC) having an input coupled to an output of the CCIA, a second ADC, having a differential input coupled to the pair of differential outputs of the low-noise differential amplifier, and may include a multiplexer for selecting between an output of the first ADC and an output of the second ADC according to a signal level of the input signal received from the MEMS microphone, so that a dynamic range of the circuit is extended by selection of the second ADC while the signal level is greater than a threshold signal level. In some example embodiments, the output of the inverting charge pump circuit may be further coupled to negative power supply terminals of the CCIA and of the first ADC. In some example embodiments, the first ADC may include an input sampling stage and a digital output stage, and the output of the inverting charge pump circuit may only supply a negative power supply rail to the low-noise differential amplifier, the CCIA, and the input sampling stage of the first ADC. In some example embodiments, the inverting charge pump circuit may be selectively enabled or disabled according to a power management control signal. The inverting charge pump may be enabled while the signal level is greater than the threshold signal level, and the inverting charge pump may be disabled while the signal level is less than the threshold signal level.

In some example embodiments, the circuits may include a switching circuit for clamping the inputs of the CCIA to a common-mode voltage of the circuit while the signal level is greater than the threshold signal level, to prevent operation of the CCIA from affecting voltages on the pair of differential outputs of the low-noise differential amplifier while the signal level is greater than the threshold signal level. In some example embodiments, the switching circuit may clamp the output of the CCIA to the common-mode voltage of the circuit while the signal level is greater than the threshold signal level. In some example embodiments, the inverting charge pump circuit may be selectively enabled or disabled according to a signal level of the input signal received from the MEMS microphone. The inverting charge pump may be enabled while the signal level is greater than the threshold signal level, the inverting charge pump may be disabled while the signal level is less than the threshold signal level.

While the disclosure has shown and described particular embodiments of the techniques disclosed herein, it will be understood by those skilled in the art that the foregoing and other changes in form, and details may be made therein without departing from the spirit and scope of the disclosure. For example, the techniques shown above may be applied to an amplifier for amplifying signals provided from another type of device.

What is claimed is:

1. A circuit for receiving an input signal from a microelectromechanical system (MEMS) microphone, the circuit comprising:
at least one input terminal for connection to at least one terminal of the MEMS microphone;
a low-noise amplifier having an input coupled to the at least one input terminal; and
an inverting charge pump circuit for generating a negative power supply voltage from an external positive voltage power supply, wherein an output of the inverting charge pump circuit is coupled to a negative power supply terminal of the low-noise amplifier.

2. The circuit of claim 1, wherein the at least one terminal of the MEMS microphone is a pair of terminals of the MEMS microphone, wherein the at least one input terminal is a pair of input terminals for connection to the pair of terminals of the MEMS microphone, and wherein the low-noise amplifier is a low-noise differential amplifier having a pair of inputs coupled to the pair of input terminals.

3. The circuit of claim 2, wherein the low-noise differential amplifier is direct-current (DC) coupled to the MEMS microphone by connection of the pair of inputs of the low-noise differential amplifier to the pair of input terminals.

4. The circuit of claim 2, wherein a pair of differential outputs of the low-noise differential amplifier are coupled to corresponding inputs of a chopped capacitively-coupled instrumentation amplifier (CCIA).

5. The circuit of claim 4, further comprising:
a first analog-to-digital converter (ADC) having an input coupled to an output of the CCIA;
a second ADC, having a differential input coupled to the pair of differential outputs of the low-noise differential amplifier; and
a multiplexer for selecting between an output of the first ADC and an output of the second ADC according to a signal level of the input signal received from the MEMS microphone, whereby a dynamic range of the circuit is extended by selection of the second ADC while the signal level is greater than a threshold signal level.

6. The circuit of claim 5, wherein the output of the inverting charge pump circuit is further coupled to negative power supply terminals of the CCIA and of the first ADC.

7. The circuit of claim 6, wherein the first ADC comprises:
an input sampling stage; and
a digital output stage, and wherein the output of the inverting charge pump circuit only supplies a negative power supply rail to the low-noise differential amplifier, the CCIA, and the input sampling stage of the first ADC.

8. The circuit of claim 7, wherein the inverting charge pump circuit is selectively enabled or disabled according to a power management control signal, wherein the inverting charge pump is enabled while the signal level is greater than the threshold signal level, and wherein the inverting charge pump is disabled while the signal level is less than the threshold signal level.

9. The circuit of claim 5, further comprising a switching circuit for clamping the inputs of the CCIA to a common-mode voltage of the circuit while the signal level is greater than the threshold signal level, to prevent operation of the CCIA from affecting voltages on the pair of differential outputs of the low-noise differential amplifier while the signal level is greater than the threshold signal level.

10. The circuit of claim 9, wherein the switching circuit further clamps the output of the CCIA to the common-mode voltage of the circuit while the signal level is greater than the threshold signal level.

11. The circuit of claim 1, wherein the inverting charge pump circuit is selectively enabled or disabled according to a signal level of the input signal received from the MEMS microphone, wherein the inverting charge pump is enabled while the signal level is greater than the threshold signal level, and wherein the inverting charge pump is disabled while the signal level is less than the threshold signal level.

12. A method of amplifying an input signal from a microelectromechanical system (MEMS) microphone with an input circuit, the method comprising:
connecting at least one terminal of the MEMS microphone to at least one input terminal of the input circuit to receive the input signal;
amplifying the input signal with a low-noise amplifier having an input coupled to the at least one input terminal; and
generating a negative power supply voltage from an external positive voltage power supply with a negative charge pump circuit; and
providing an output of the inverting charge pump circuit to a negative power supply terminal of the low-noise amplifier.

13. The method of claim 12, wherein the at least one terminal of the MEMS microphone is a pair of terminals of the MEMS microphone, wherein the at least one input terminal is a pair of input terminals for connection to the pair of terminals of the MEMS microphone, wherein the low-noise amplifier is a low-noise differential amplifier, and wherein the method further comprises coupling the pair of input terminals to a differential pair of inputs of the low-noise differential amplifier.

14. The method of claim 13, wherein coupling of the differential pair of input terminals to the differential pair of inputs of the low-noise differential amplifier comprises connecting the differential pair of inputs of the low-noise differential amplifier to the pair of input terminals.

15. The method of claim 13, further comprising coupling a pair of differential outputs of the low-noise differential amplifier to corresponding inputs of a chopped capacitively-coupled instrumentation amplifier (CCIA).

16. The method of claim 15, further comprising:
first converting an output of the CCIA to a first digital representation with a first analog-to-digital converter (ADC) having an input coupled to an output of the CCIA;
second converting an output of the low-noise differential amplifier to a second digital representation with a second ADC having a differential input coupled to the pair of differential outputs of the low-noise differential amplifier; and
selecting between an output of the first ADC and an output of the second ADC according to a signal level of the input signal received from the MEMS microphone, whereby a dynamic range of the circuit is extended by selection of the second ADC while the signal level is greater than a threshold signal level.

17. The method of claim 16, wherein providing the output of the inverting charge pump circuit further provides the output of the inverting charge pump circuit to negative power supply terminals of the CCIA and to negative supply terminals of the first ADC.

18. The method of claim 17, wherein the first ADC comprises an input sampling stage and a digital output stage, and wherein the providing of the output of the inverting charge pump circuit only supplies a negative power supply rail to the low-noise differential amplifier, the CCIA, and the input sampling stage of the first ADC.

19. The method of claim 18, further comprising selectively enabling or disabling the inverting charge pump circuit according to a power management control signal, wherein the inverting charge pump is enabled while the signal level is greater than the threshold signal level, and wherein the inverting charge pump is disabled while the signal level is less than the threshold signal level.

20. The method of claim 16, further comprising clamping the inputs of the CCIA to a common-mode voltage of the circuit while the signal level is greater than the threshold signal level, to prevent operation of the CCIA from affecting voltages on the pair of differential outputs of the low-noise differential amplifier while the signal level is greater than the threshold signal level.

21. The method of claim 20, further comprising clamping the output of the CCIA to the common-mode voltage of the circuit while the signal level is greater than the threshold signal level.

22. The method of claim 12, further comprising selectively enabling or disabling the inverting charge pump circuit according to a power management control signal, wherein the inverting charge pump is enabled while the signal level is greater than the threshold signal level, and wherein the inverting charge pump is disabled while the signal level is less than the threshold signal level.
